(19) United States
(12) Patent Application Publication
(10) Pub. No.: US 2025/0210115 A1
(43) Pub. Date: Jun. 26, 2025

(54) ENHANCED PROACTIVE READ DISTURB DETECTION IN A MEMORY SUB-SYSTEM

(71) Applicant: Micron Technology, Inc., Boise, ID (US)

(72) Inventors: Peng Zhang, Los Altos, CA (US); Zhongguang Xu, San Jose, CA (US); Murong Lang, San Jose, CA (US); Zhenming Zhou, San Jose, CA (US)

(21) Appl. No.: 18/988,241

(22) Filed: Dec. 19, 2024

Related U.S. Application Data
(60) Provisional application No. 63/612,935, filed on Dec. 20, 2023.

(51) Int. Cl. G11C 16/34; G11C 16/08; G11C 16/26

(52) U.S. Cl. CPC G11C 16/3427; G11C 16/08; G11C 16/26

(57) ABSTRACT

A processing device in a memory sub-system performs a read disturb scan on a block of a memory device to detect that a read disturb scan has been triggered for a partial block of the memory device. The processing device initiates one or more programmed wordline scans of the one or more wordlines having associated memory cells that have been programmed. Responsive to the one or more wordlines having associated memory cells that have been programmed passing the one or more programmed wordline scans, the processing device initiates an unprogrammed wordline scan of the one or more wordlines having associated memory cells that are empty. Responsive to the one or more wordlines having associated memory cells that are empty failing the one or more unprogrammed wordline scans, the processing device marks the partial block as closed to prevent additional programming of the partial block.

### RELATED APPLICATIONS

This application claims the benefit of U.S. Provisional Patent Application No. 63/612,935, filed Dec. 20, 2023, entitled “Enhanced Proactive Read Disturb Detection in a Memory Sub-system” which is incorporated by reference herein.

### TECHNICAL FIELD

Embodiments of the disclosure relate generally to memory sub-systems, and more specifically, relate to enhanced proactive read disturb detection in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2 is a flow diagram of an example method of performing a read disturb scan in a memory sub-system in accordance with some embodiments of the present disclosure.

FIG. 3 is a diagram illustrating a partial block in accordance with some embodiments of the present disclosure.

FIG. 4 is a flow diagram of a programmed and unprogrammed wordline scan flow in accordance with some embodiments of the present disclosure.

FIG. 5 is a block diagram of an example computer system in which embodiments of the present disclosure may operate.

### DETAILED DESCRIPTION

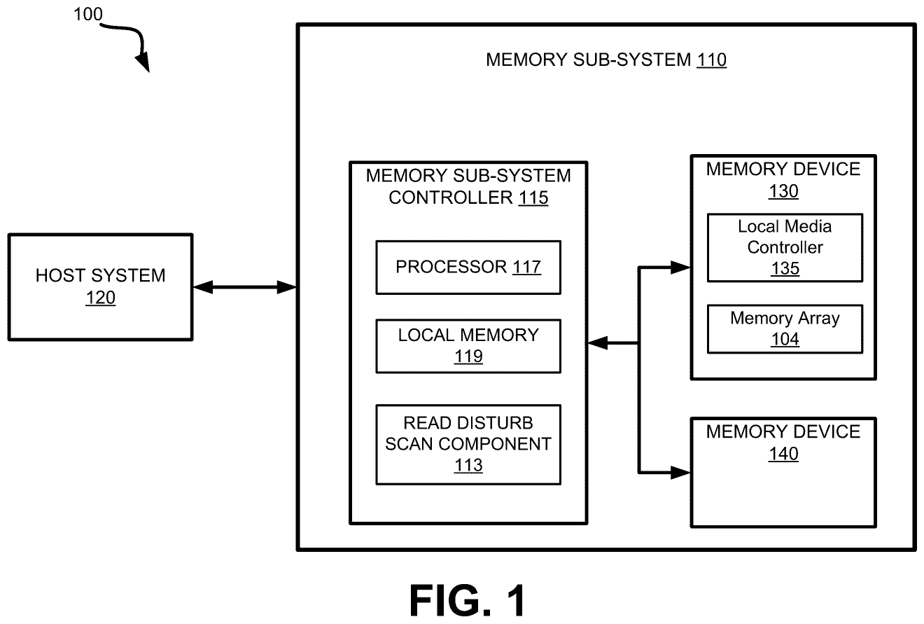

Aspects of the present disclosure are directed to enhanced proactive read disturb detection in a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane.

One example of a memory sub-system is a solid-state drive (SSD) that includes one or more non-volatile memory devices and a memory sub-system controller to manage the non-volatile memory devices. A given segment of one of those memory devices (e.g., a block) can be characterized based on the programming state of the memory cells associated with wordlines contained within the segment. At certain intervals, the memory sub-system can perform a data integrity check (also referred to herein as a “scan”) to verify that the data stored at a segment does not include any errors or has not exceeded a threshold risk of error. During the data integrity check, one or more reliability statistics are determined for data stored at the block and may be used to indicate the health of the block. One example of a reliability statistic is raw bit error rate (RBER). The RBER corresponds to the number of bit errors per unit of time that the data stored at the block experiences.

Read disturb (RD) is a phenomenon that can occur in memory devices, where reading data from memory cells associated with a given wordline impacts the threshold voltages of memory cells associated with unselected wordlines of the same block. When reading a page from one or more memory cells, a read voltage is applied to the associated selected wordline. This voltage can cause electrons to migrate to memory cells associated with one or more other wordlines adjacent to the selected wordline unintentionally, which can compromise data integrity and cause errors during read operations since the memory cells no longer accurately represent the data they were meant to hold. If the changes in the neighboring cells are significant enough, this can lead to data corruption or bit errors in those cells. This is referred to as a “read disturb” error. The risk of read disturb increases with the number of read functions performed, which can result in a higher RBER or affect other reliability statistics.

To prevent read disturb errors, management techniques are employed. One such management technique is read disturb detection. Read disturb detection is a feature that relies on frequent scans of the memory cells associated with randomly-selected wordlines to detect degradation from reading and screen out blocks with a certain number of memory cells suffering from read disturb. Read disturb detection can be performed through a read disturb scan, which is a procedure performed on the memory device to identify or measure the vulnerability of memory cells to read disturb. If the read disturb scan indicates a high error rate associated with data stored at a block, in a process referred to herein as “folding,” the data stored at the block is relocated to a new, less frequently read, block of the memory sub-system, and the original block is rewritten or erased (herein referred to as “refreshed”) to mitigate data corruption risk.

A block may comprise of one or more wordlines having associated memory cells that have been programmed (herein referred to as “programmed wordlines”) and one or more wordlines having associated memory cells that are empty (herein referred to as “unprogrammed wordlines”). This block composition is herein referred to as a “partial block.”

A conventional read disturb scan may include a number of scans. For example, an unprogrammed wordline scan is a check typically performed during a read disturb scan. An unprogrammed wordline scan will check erased memory cells of a randomly-selected unprogrammed wordline for significant charge gain to prevent any future errors. Erased cells on unprogrammed wordlines, having no or minimal charge (“1”), are more susceptible to read disturb than programmed cells (on programmed wordlines), as they have a weaker electric screening effect and thus, a stronger electric field across the tunnel oxide. As a result, the erased cells on unprogrammed wordlines have a higher risk of read disturb error if they continue to be programmed. In the case of an unprogrammed wordline scan, the selected wordline will be checked to see if the number of associated memory cells with a charge (“0”) exceeds a predetermined threshold.

As erased cells are more susceptible to read disturb errors than programmed cells, unprogrammed wordlines have a higher unprogrammed wordline scan failure risk than programmed wordlines, resulting in a higher rate of folding. Furthermore, even if an unprogrammed wordline fails the unprogrammed wordline scan, this does not mean the programmed wordlines are at risk. It may be possible that the programmed wordlines are still within the threshold criteria for a programmed wordline scan and do not call for the partial block to be folded. Thus, folding such a partial block ties up system resources that could be used for other operations and adds additional wear to the physical media used in the memory sub-system unnecessarily. As a read disturb scan is triggered when a host is reading the data, it has a high priority, so it will increase system latency and affect QoS.

Aspects of the present disclosure address the above and other deficiencies by implementing an enhanced read disturb detection technique in a memory sub-system. In an embodiment, a non-volatile memory device contains a block, which is available for reading and writing to under normal operations, and which includes one or more programmed wordlines and one or more unprogrammed wordlines. When a read disturb scan is triggered, one or more scans directed toward the programmed wordlines can be initiated. Responsive to determining that these programmed wordline scans pass, control logic in the memory sub-system can initiate an unprogrammed wordline scan to scan one or more wordlines of the block with empty memory cells. If a significant charge gain is present on the memory cells of the unprogrammed wordline such that it indicates a risk of read disturb, the unprogrammed wordline scan will fail. Rather than initiating the folding process for such a block, the block can instead be marked “closed,” thereby preserving the data already written into the block, and signaling that the block is not to be programmed any further. Each block in the memory device has a cursor, marked in the metadata as open or closed. An “open” cursor means that a block is healthy enough to continue to be programmed. When an unprogrammed wordline scan fails, the cursor is marked as “closed.” When an unprogrammed wordline scan passes, the cursor remains marked “open.” In an embodiment, upon the unprogrammed wordline scan passing, the read disturb scan flow may end with the conclusion that the partial block has passed the read disturb scan.

The programmed wordline scans can vary in execution. For example, in one embodiment, a programmed wordline scan may check the reliability statistic of a programmed wordline that has been randomly-selected from those adjacent to the wordline which is being read. The check will determine whether that wordline satisfies a threshold criterion based on a reliability statistic of the wordline In another embodiment, the programmed wordline scan may check a wordline that has been randomly-selected from the partial block. In either example, if a reliability statistic of the wordline fails to satisfy the criterion of the programmed wordline scan, the block will be folded. If the wordline passes the programmed wordline scan, then the read disturb scan may continue in its scan flow.

In an embodiment, the read disturb scan is triggered by a die-based read counter. The die-based read counter is a specific counter for each die within the NAND flash memory system that keeps track of how many times each block of memory within the die has been read since it was last erased. Once a specified threshold number of read operations has been reached, indicating a risk of read disturb, a read disturb scan will initiate to ensure the health of the blocks.

Advantages of the approach described herein include, but are not limited to, improved performance in the memory sub-system and an improved QoS. The enhanced read disturb detection scan flow can reduce unnecessary folding for a read disturb scan of an open partial block (i.e. a block with unprogrammed wordlines). Since read disturb detection is a foreground task during and intermixed with Host operations, the invention can reduce latency and improve QoS performance by reducing folding rate and only initiating folding when necessary. In addition, this invention may be applied to any product with a read disturb scan module. This enhanced read disturb scan flow will not sacrifice any effectiveness in detecting and isolating read disturb risks.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., one or more memory device(s) 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., the one or more memory device(s) 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative- or (NOR) flash memory, electrically erasable programmable read-only memory (EEPROM).

A memory sub-system controller 115 (or controller 115 for simplicity) can communicate with the memory device(s) 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 130. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some embodiments, the memory device(s) 130 include local media controllers 135 that operate in conjunction with memory sub-system controller 115 to execute operations on one or more memory cells of the memory device(s) 130. An external controller (e.g., memory sub-system controller 115) can externally manage the memory device 130 (e.g., perform media management operations on the memory device(s) 130). In some embodiments, a memory device 130 is a managed memory device, which is a raw memory device (e.g., memory array 104) having control logic (e.g., local controller 135) for media management within the same memory device package. An example of a managed memory device is a managed NAND (MNAND) device. Memory device(s) 130, for example, can each represent a single die having some control logic (e.g., local media controller 135) embodied thereon. In some embodiments, one or more components of memory sub-system 110 can be omitted.

In one embodiment, the memory sub-system 110 includes a read disturb scan component 113 that can perform a read disturb scan on memory device 130. Read disturb scan component 113 performs a read disturb scan on a block of memory device 130 to detect degradation from reading and screen out blocks suffering from read disturb. Initially, read disturb scan component 113 detects that a read disturb scan has been triggered for a partial block of memory device 130. In one embodiment the read disturb scan may be triggered in response to a threshold number of read operations being performed on memory device 130 in memory sub-system 110 since a previous read disturb scan was performed. Read disturb scan component 113 further initiates one or more programmed wordline scans of the one or more wordlines having associated memory cells that have been programmed. Responsive to the one or more wordlines having associated memory cells that have been programmed passing the one or more programmed wordline scans, read disturb scan component 113 can initiate an unprogrammed wordline scan of the one or more wordlines having associated memory cells that are empty. Furthermore, responsive to the one or more wordlines having associated memory cells that are empty failing the one or more unprogrammed wordline scans, read disturb scan component 113 will mark the partial block of memory device 130 as closed to prevent additional programming of the partial block. Further details with regard to the operations of read disturb scan component 113 are described below.

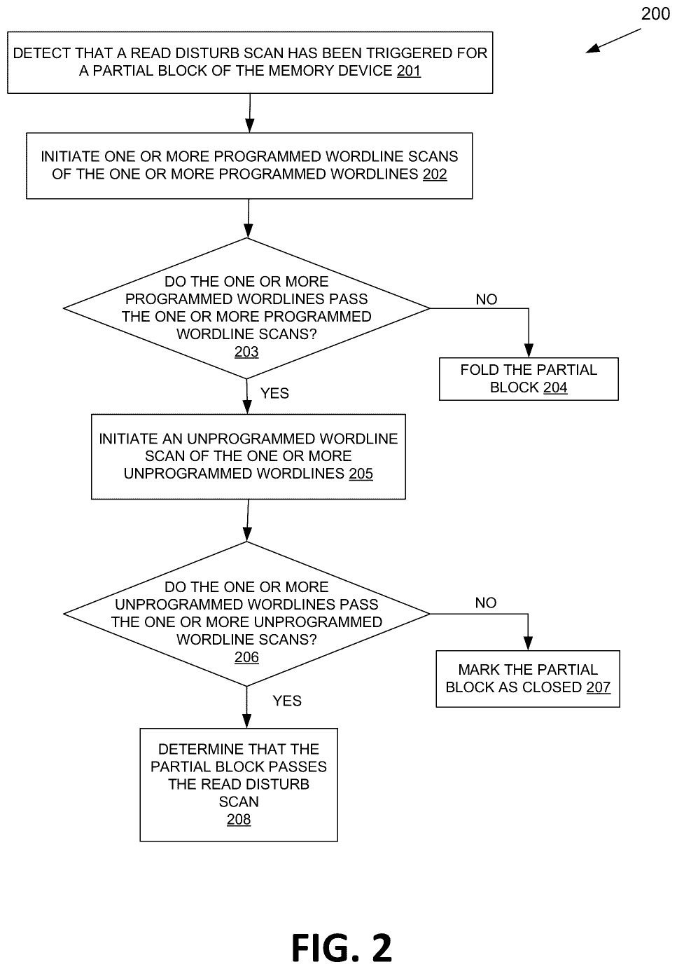

FIG. 2 is a flow diagram of an example method of performing a read disturb scan in a memory sub-system in accordance with some embodiments of the present disclosure. The method depicted in 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by read disturb scan component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

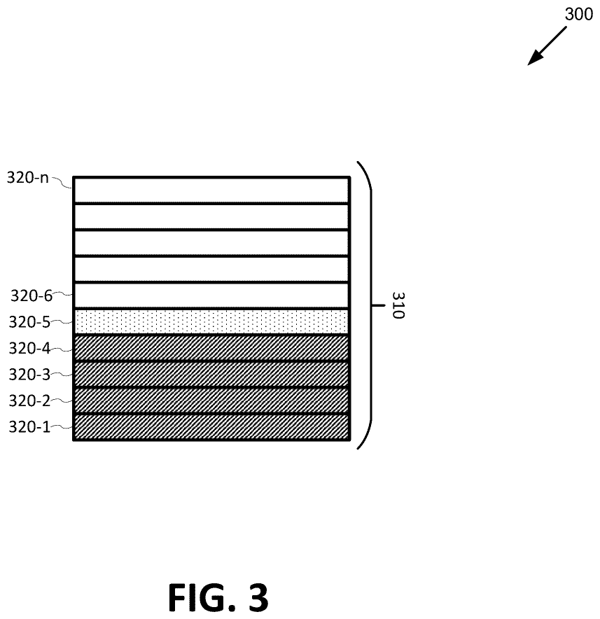

At operation 201, the processing logic (e.g. read disturb scan component 113) detects that a read disturb scan has been triggered for a partial block of the memory device, wherein the partial block comprises one or more wordlines having associated memory cells that have been programmed and one or more wordlines that have associated memory cells that are empty. In one embodiment the read disturb scan may be triggered in response to a threshold number of read operations being performed on memory device 130 since a previous read disturb scan was performed. An example of a partial block 300 is illustrated in FIG. 3.

FIG. 3, is a diagram 300 illustrating a partial block 310 in accordance with some embodiments of the present disclosure. As shown, the partial block 310 comprises a number of individual portions (e.g. wordlines). Wordlines 320-1 through 320-n represent wordlines of the partial block 310, each having associated memory cells. Wordlines 320-1 through 320-4 represent programmed wordlines, each having associated memory cells that have been programmed. Wordlines 320-5 through 320-n represent unprogrammed wordlines, each having associated memory cells that are empty. Wordline 320-5 represents an unprogrammed wordline that is exhibiting read disturb and may pose a risk to future read and write operations.

Referring again to FIG. 2, at operation 202, responsive to detection of the read disturb scan trigger, the processing logic initiates one or more programmed wordline scans of the one or more wordlines having associated memory cells that have been programmed, wordlines 320-1 through 320-4, to determine whether a reliability statistic associated with the wordline being scanned satisfies a threshold criterion. In an embodiment, the programmed wordline scan may check whether a reliability statistic of a programmed wordline randomly-selected from those adjacent to that which is being read satisfies a threshold criterion. In another embodiment, a programmed wordline scan will check if the reliability statistic of a randomly-selected programmed wordline satisfies a threshold criterion.

At operation 203, the processing logic determines whether a reliability statistic associated with the one or more wordlines having associated memory cells that have been programmed being scanned satisfies a threshold criterion. During a scan, one or more reliability statistics are determined for data stored at the block. One example of a reliability statistic is raw bit error rate (RBER). The RBER corresponds to a number of bit errors per unit of time that the data stored at the block experiences.

Responsive to the one or more wordlines having associated memory cells that have been programmed failing the one or more programmed wordline scans, at operation 204, the processing logic will fold the block. Failing a programmed wordline scan occurs when a reliability statistic associated with the wordline being scanned does not satisfy a threshold criterion, indicating a high error rate associated with data stored at a block. For example, if the RBER exceeds a predetermined threshold, the threshold criterion is not satisfied and the programmed wordline being scanned will fail the programmed wordline scan. To fold the partial block 410, the processing logic 113 can copy the data from the one or more wordlines having associated memory cells that have been programmed to a different block of the memory device 130 and refresh the partial block 410 to mitigate data corruption risk.

Responsive to the one or more wordlines having associated memory cells that have been programmed passing the one or more programmed wordline scans, at operation 205, the processing logic can initiate an unprogrammed wordline scan of the one or more wordlines having associated memory cells that are empty, such as wordlines 420-5 through 420-n, to determine if the reliability statistic of a randomly-selected unprogrammed wordline satisfies a threshold criterion.

At operation 206, the processing logic determines whether a reliability statistic associated with the one or more wordlines having associated memory cells that are empty being scanned satisfies a threshold criterion. Different threshold criteria may be applied depending on the reliability statistic used. As in operation 203, one or more reliability statistics are determined for data stored at the partial block and measured against a threshold criterion.

Responsive to the one or more wordlines having associated memory cells that are empty failing the one or more unprogrammed wordline scans, at operation 207, the processing logic marks the partial block as closed to prevent additional programming of the partial block. In the memory device, every block has a cursor, which is indicated in the metadata as either open or closed. A block with an “open” cursor is considered robust enough for ongoing programming. If a scan of an unprogrammed wordline is unsuccessful, the processing logic sets the cursor for that block to “closed.” By marking the partial block as closed, it allows for the existing data within the partial block 410 to be preserved and signals that the partial block is not to be programmed any further.

Responsive to the one or more wordlines having associated memory cells that are empty passing the one or more unprogrammed wordline scans, at operation 208, the processing logic determines that the partial block passes the read disturb scan. Passing the read disturb scan indicates that the partial block and the wordlines inside are reliable enough to read and write to.

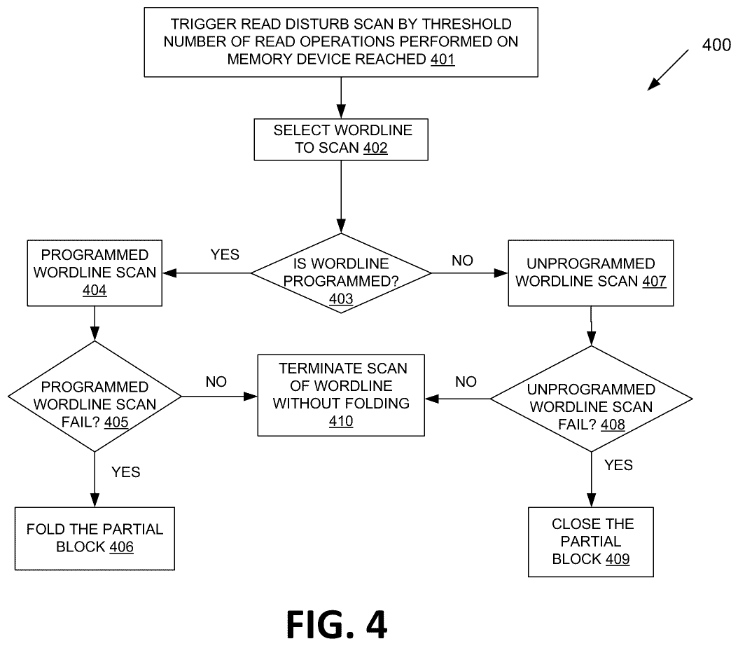

FIG. 4 is a flow diagram 400 of a programmed and unprogrammed wordline scan flow in accordance with some embodiments of the present disclosure. The flow depicted in 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the flow 400 is performed by read disturb scan component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 401, the processing logic detects that a read disturb scan has been triggered for a partial block of the memory device. In an embodiment, the read disturb scan may be triggered in response to a threshold number of read operations being performed on memory device 130 since a previous read disturb scan was performed.

At operation 402, the processing logic selects a wordline to scan. Depending on the embodiment, the wordline selection method may vary. In an embodiment, the one or more wordline scans will scan a wordline randomly-selected from those adjacent to a wordline being read. For example, if wordline 320-2 were being read, the processing logic will randomly select one of wordlines 320-1 and 320-3. In another embodiment, the selected wordline may be randomly-selected from the one or more wordlines having associated memory cells that have been programmed. Furthermore, in an embodiment, the selected wordline may be randomly-selected from the one or more wordlines having associated memory cells that are empty.

At operation 403, the processing logic determines whether the selected wordline is a programmed wordline or an unprogrammed wordline. In an embodiment, if the selected wordline is a programmed wordline, the processing logic will initiate a programmed wordline scan at operation 404. In an embodiment, if the selected wordline is an unprogrammed wordline, and a programmed wordline scan has not yet occurred, the processing logic will select a new wordline at operation 402 and check it at operation 403 until a programmed wordline has been selected and a programmed wordline scan has occurred. In an embodiment, if the selected wordline is an unprogrammed wordline, and a programmed wordline scan has occurred, the processing logic will initiate an unprogrammed wordline scan at operation 407.

At operation 404, the processing logic initiates one or more programmed wordline scans of the one or more programmed wordlines, represented in FIG. 3 as wordlines 320-1 through 320-4, to determine whether a reliability statistic associated with the one or more wordlines being scanned satisfies a threshold criterion.

At operation 405, just as at operation 203, the processing logic determines whether a reliability statistic associated with the programmed wordline being scanned satisfies a threshold criterion. This threshold criterion refers to a specific set of conditions or parameters that determine whether a partial block is sufficiently healthy for further programming. A partial block's health is indicated by the block's risk of read disturb, which can be assessed using one or more reliability statistics determined for data stored at the partial block 310. Different threshold criteria may be applied depending on the reliability statistic used. A criterion may be satisfied if the reliability statistic is less than (or greater than, depending on the reliability statistic used) a threshold value indicating the acceptable level of risk of read disturb. When the criterion is not satisfied, this indicates an unacceptable risk of read disturb and the scan will fail. As mentioned in operation 203, an example of a reliability statistic is raw bit error rate (RBER). The RBER corresponds to the number of bit errors per unit of time that the data stored at the block experiences. If the RBER of a wordline exceeds a predetermined threshold criterion, the programmed wordline being scanned will fail the programmed wordline scan.

Responsive to the one or more programmed wordlines failing the one or more programmed wordline scans, at operation 406, the processing logic will fold the block. Just as in operation 204, failing a programmed wordline scan occurs when a reliability statistic associated with the wordline being scanned does not satisfy a threshold criterion, indicating a high error rate associated with data stored at a block. Folding the partial block 310 entails the processing logic 113 copying the data from the one or more wordlines having associated memory cells that have been programmed to a different block of the memory device 130 and the partial block 310 rewritten or erased (herein referred to as “refreshed”) to mitigate data corruption risk.

Responsive to the one or more programmed or unprogrammed wordlines passing the one or more programmed or unprogrammed wordline scans, at operation 410, the processing logic will terminate the one or more programmed or unprogrammed wordline scans without folding the partial block 310. That is, a reliability statistic associated with the one or more scanned wordlines satisfies the threshold criterion such that the scanned wordlines do not pose a risk of read disturb.

At operation 407, the processing logic initiates one or more programmed wordline scans of the one or more unprogrammed wordlines, represented in FIG. 3 as wordlines 320-5 through 320-n, to determine whether a reliability statistic associated with the one or more wordlines being scanned satisfies a threshold criterion.

At operation 408, just as at operation 206, the processing logic determines whether a reliability statistic associated with the unprogrammed wordline being scanned satisfies a threshold criterion. As in operation 405, a threshold criterion refers to a specific set of conditions or parameters that determine whether a partial block is sufficiently healthy for further programming. A partial block's health is indicated by the block's risk of read disturb, which can be assessed using one or more reliability statistics determined for data stored at the partial block 310. Different threshold criteria may be applied depending on the reliability statistic used. A criterion may be satisfied if the reliability statistic is less than (or greater than, depending on the reliability statistic used) a threshold value indicating the acceptable level of risk of read disturb. Failing to satisfy the criterion indicates an unacceptable risk of read disturb and the scan will fail. For example, reliability statistic may be based on a count and whether that count exceeds a set threshold. In an unprogrammed wordline scan, an unprogrammed wordline may be checked to see if the number of associated memory cells with more than minimal charge (“0”) exceeds a predetermined threshold.

Responsive to the one or more unprogrammed wordlines failing the one or more unprogrammed wordline scans, at operation 409, just as at operation 207, the processing logic marks the partial block as closed. By marking the cursor of the partial block as closed in the metadata, it allows for the existing data within the partial block 310 to be preserved and signals that the partial block is not to be programmed any further.

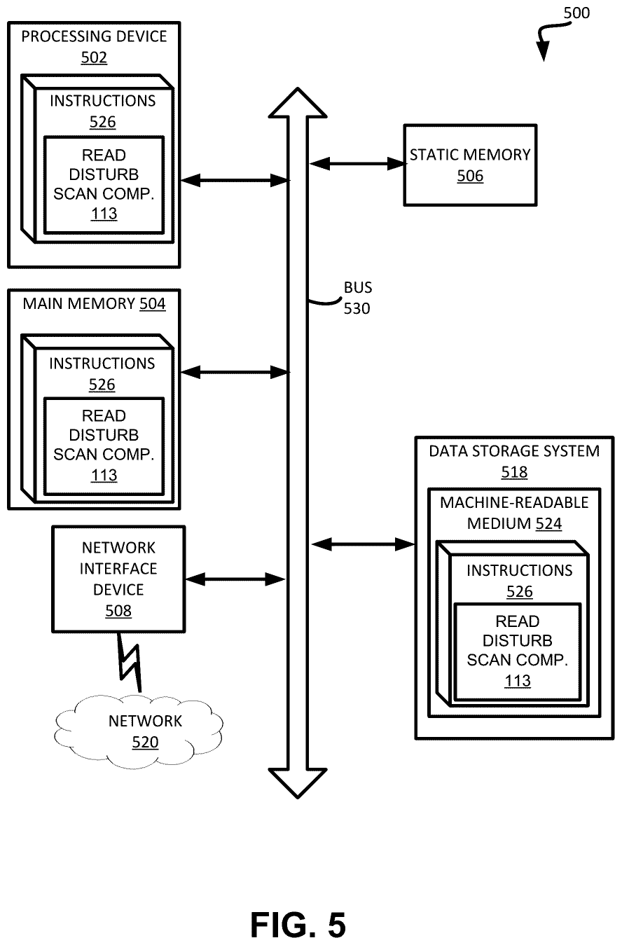

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the read disturb scan component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to the read disturb scan component 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device;
a processing device, operatively coupled with the memory device, to perform operations comprising:
detecting that a read disturb scan has been triggered for a partial block of the memory device, wherein the partial block comprises one or more wordlines having associated memory cells that have been programmed and one or more wordlines that have associated memory cells that are empty;
initiating one or more programmed wordline scans of the one or more wordlines having associated memory cells that have been programmed;
responsive to the one or more wordlines having associated memory cells that have been programmed passing the one or more programmed wordline scans, initiating an unprogrammed wordline scan of the one or more wordlines having associated memory cells that are empty; and
responsive to the one or more wordlines having associated memory cells that are empty failing the one or more unprogrammed wordline scans, marking the partial block as closed to prevent additional programming of the partial block.

2. The system of claim 1, wherein the one or more programmed wordline scans will scan a first wordline adjacent to a wordline being read to determine whether a reliability statistic associated with the first wordline satisfies a threshold criterion.

3. The system of claim 1, wherein the one or more programmed wordline scans will scan a first wordline that has been randomly-selected from the one or more wordlines having associated memory cells that have been programmed to determine whether a reliability statistic associated with the first wordline satisfies a threshold criterion.

4. The system of claim 1, wherein the one or more unprogrammed wordline scans will scan a first wordline that has been randomly-selected from the one or more wordlines having associated memory cells that are empty to determine whether a number of the associated memory cells that have been programmed satisfies a threshold criterion.

5. The system of claim 1, wherein the processing device is configured to perform operations further comprising:
responsive to the one or more wordlines having associated memory cells that are programmed failing the one or more programmed wordline scans, copying data from the one or more wordlines having associated memory cells that have been programmed to a different block of the memory device and refreshing the partial block.

6. The system of claim 1, wherein the processing device is configured to perform operations further comprising:
responsive to the one or more wordlines having associated memory cells that are empty passing the one or more unprogrammed wordline scans, determining that the partial block passes the read disturb scan.

7. The system of claim 1, wherein the read disturb scan is triggered in response to a threshold number of read operations being performed on the memory device since a previous read disturb scan was performed.

8. A method comprising:
detecting that a read disturb scan has been triggered for a partial block of a memory device, wherein the partial block comprises one or more wordlines having associated memory cells that have been programmed and one or more wordlines that have associated memory cells that are empty;
initiating one or more programmed wordline scans of the one or more wordlines having associated memory cells that have been programmed;
responsive to the one or more wordlines having associated memory cells that have been programmed passing the one or more programmed wordline scans, initiating an unprogrammed wordline scan of the one or more wordlines having associated memory cells that are empty; and
responsive to the one or more wordlines having associated memory cells that are empty failing the one or more unprogrammed wordline scans, marking the partial block as closed to prevent additional programming of the partial block.

9. The method of claim 8, wherein the one or more programmed wordline scans will scan a first wordline adjacent to a wordline being read to determine whether a reliability statistic associated with the first wordline satisfies a threshold criterion.

10. The method of claim 8, wherein the one or more programmed wordline scans will scan a first wordline that has been randomly-selected from the one or more wordlines having associated memory cells that have been programmed to determine whether a reliability statistic associated with the first wordline satisfies a threshold criterion.

11. The method of claim 8, wherein the one or more unprogrammed wordline scans will scan a first wordline that has been randomly-selected from the one or more wordlines having associated memory cells that are empty to determine whether a number of the associated memory cells that have been programmed satisfies a threshold criterion.

12. The method of claim 8, further comprising:
responsive to the one or more wordlines having associated memory cells that are programmed failing the one or more programmed wordline scans, copying data from the one or more wordlines having associated memory cells that have been programmed to a different block of the memory device and refreshing the partial block.

13. The method of claim 8, further comprising:
responsive to the one or more wordlines having associated memory cells that are empty passing the one or more unprogrammed wordline scans, determining that the partial block passes the read disturb scan.

14. The method of claim 8, wherein the read disturb scan is triggered in response to a threshold number of read operations being performed on the memory device since a previous read disturb scan was performed.

15. A non-transitory computer-readable storage medium comprising instructions that, when executed by a processing device, cause the processing device to perform operations comprising:
detecting that a read disturb scan has been triggered for a partial block of a memory device, wherein the partial block comprises one or more wordlines having associated memory cells that have been programmed and one or more wordlines that have associated memory cells that are empty;
initiating one or more programmed wordline scans of the one or more wordlines having associated memory cells that have been programmed;
responsive to the one or more wordlines having associated memory cells that have been programmed passing the one or more programmed wordline scans, initiating an unprogrammed wordline scan of the one or more wordlines having associated memory cells that are empty; and
responsive to the one or more wordlines having associated memory cells that are empty failing the one or more unprogrammed wordline scans, marking the partial block as closed to prevent additional programming of the partial block.

16. The non-transitory computer-readable storage medium of claim 15, wherein the one or more programmed wordline scans will scan a first wordline adjacent to a wordline being read to determine whether a reliability statistic associated with the first wordline satisfies a threshold criterion.

17. The non-transitory computer-readable storage medium of claim 15, wherein the one or more programmed wordline scans will scan a first wordline that has been randomly-selected from the one or more wordlines having associated memory cells that have been programmed to determine whether a reliability statistic associated with the first wordline satisfies a threshold criterion.

18. The non-transitory computer-readable storage medium of claim 15, wherein the one or more unprogrammed wordline scans will scan a first wordline that has been randomly-selected from the one or more wordlines having associated memory cells that are empty to determine whether a number of the associated memory cells that have been programmed satisfies a threshold criterion.

19. The non-transitory computer-readable storage medium of claim 15, wherein performing the read disturb scan comprises:
responsive to the one or more wordlines having associated memory cells that are programmed failing the one or more programmed wordline scans, copying data from the one or more wordlines having associated memory cells that have been programmed to a different block of the memory device and refreshing the partial block.

20. The non-transitory computer-readable storage medium of claim 15, wherein performing the read disturb scan comprises:
responsive to the one or more wordlines having associated memory cells that are empty passing the one or more unprogrammed wordline scans, determining that the partial block passes the read disturb scan.
